(19) United States
(12) Patent Application Publication
(10) Pub. No.: US 2025/0137136 A1
(43) Pub. Date: May 1, 2025

(54) LAYER DEPOSITION APPARATUS AND LAYER DEPOSITION METHOD

(71) Applicant: Samsung Electronics Co., Ltd., Suwon-si (KR)

(72) Inventors: Hunyong Park, Suwon-si (KR); Yeontae Kim, Suwon-si (KR); Janghwi Lee, Suwon-si (KR); Sangwoo Bae, Suwon-si (KR); Jungchul Lee, Suwon-si (KR)

(21) Appl. No.: 18/919,340

(22) Filed: Oct. 17, 2024

(30) Foreign Application Priority Data
Nov. 1, 2023 (KR) 10-2023-0149030

(51) Int. Cl. C23C 16/48

(52) U.S. Cl. CPC C23C 16/482

(57) ABSTRACT

A layer deposition apparatus includes a process chamber configured to provides a space for processing a substrate, the process chamber including an upper chamber and a lower chamber that define an inner space; a substrate support disposed within the process chamber and configured to support the substrate; a lamp heating portion disposed above the upper chamber outside the process chamber and including a plurality of light sources configured to irradiate light onto the substrate through the upper chamber; and an interference thin layer pattern disposed on an upper surface of the upper chamber and configured to reflect at least a portion of light from the plurality of light sources.

### CROSS-REFERENCE TO RELATED APPLICATIONS

This application claims priority to Korean Patent Application No. 10-2023-0149030, filed in the Korean Intellectual Property Office (KIPO) on Nov. 1, 2023, the contents of which are herein incorporated by reference in its entirety.

### BACKGROUND

To manufacture a semiconductor device, a layer deposition process may be performed to form a thin layer on a semiconductor substrate. The thin layer may be formed to have a single crystal structure by an epitaxial process among the layer deposition processes. During the epitaxial process, a substrate may be placed on a susceptor in a process chamber, and a heating source such as a plurality of heating lamps may be disposed above or below the substrate to heat the substrate. However, light from the heating lamps may intensively overlap in some areas on the substrate, resulting in differences in the distribution of the amount of light irradiated for each area of the substrate. Accordingly, there is a problem in that non-uniform temperature distribution occurs across the entire substrate, resulting in thickness deviation of the thin layer.

### SUMMARY

In general, in some aspects, the present disclosure is directed toward a layer deposition apparatus capable of forming a thin layer with a uniform thickness, and a plasma processing system including a plasma control apparatus.

According to some implementations, the present disclosure is directed to a layer deposition apparatus that includes a process chamber configured to provide a space for processing a substrate, the process chamber including an upper chamber and a lower chamber that define an inner space; a substrate support disposed within the process chamber and configured to support the substrate; a lamp heating portion disposed above the upper chamber outside the process chamber and including a plurality of light sources configured to irradiate light onto the substrate through the upper chamber; and an interference thin layer pattern disposed on an upper surface of the upper chamber and configured to reflect at least a portion of light from the plurality of light sources.

According to some implementations, the present disclosure is directed to a layer deposition apparatus that includes a dome-shaped first transparent chamber; a dome-shaped second transparent chamber; a substrate support disposed between the first transparent chamber and the second transparent chamber, the substrate support being configured to support a substrate; a lamp heating portion disposed above the first transparent chamber and including a plurality of light sources configured to irradiate light onto the substrate through the first transparent chamber; and an interference thin layer pattern disposed on an upper surface of the first transparent chamber, the interference thin layer including first thin layers and second thin layers having different refractive indexes that are alternately stacked to reflect at least a portion of light from the plurality of light sources.

According to some implementations, the present disclosure is directed to a method of a layer deposition method, in which a process chamber including an upper chamber and a lower chamber that define a space for processing a substrate is provided. An interference thin layer pattern is formed on an upper surface of the upper chamber. The substrate is loaded onto a substrate support within the process chamber. Light from a plurality of light sources disposed above the upper chamber is irradiated onto the substrate through the interference thin layer pattern and the upper chamber. A thin layer is deposited on the substrate.

According to some implementations, the present disclosure is directed to a thin layer deposition apparatus that includes a process chamber including an upper chamber and a lower chamber, a substrate support, a first reflection housing, a first lamp heating portion, and an interference thin layer pattern. The interference thin layer pattern may have an annular shape and may cover an annular area at a specific radius of the upper surface of the upper chamber. The interference thin film pattern may serve as an optical filter having a reflectance of at least 50% in a wavelength bandwidth of 800 nm to 2,000 nm. The interference thin film pattern may prevent a light overlap phenomenon in which light from first light sources of the first lamp heating portion intensively overlaps in some areas on a substrate on the substrate support. Accordingly, a uniform thin film may be formed.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a layer deposition apparatus in accordance with some implementations.

FIG. 2 is a perspective view illustrating an example of a lamp heating portion including a plurality of light sources disposed in an upper portion of a first chamber of the layer deposition apparatus of FIG. 1 in accordance with some implementations.

FIG. 3 is a graph illustrating an example of a spectrum according to wavelength of light emitted from the light source of FIG. 2 in accordance with some implementations.

FIG. 4 is a graph illustrating an example of light transmittance of the first chamber with respect to light emitted from the light source of FIG. 2 in accordance with some implementations.

FIG. 5 is a plan view illustrating an example of an interference thin layer pattern provided on an upper surface of a first chamber in accordance with some implementations.

FIG. 6 is a cross-sectional view taken along the line A-A′ in FIG. 5 in accordance with some implementations.

FIG. 7 is a cross-sectional view illustrating the interference thin layer pattern of FIG. 5 that blocks some of the light from the first light sources in accordance with some implementations.

FIG. 8 is a cross-sectional view illustrating an example of an interference thin layer pattern in which first thin layers and second thin layers are alternately stacked on a transparent substrate in accordance with some implementations.

FIG. 9 is a cross-sectional view illustrating an example of an interference thin layer pattern formed on the upper surface of the first chamber in accordance with some implementations.

FIG. 10 is a graph illustrating an example of reflectance of an interference thin layer pattern in accordance with some implementations.

FIG. 11 is a graph illustrating an example of reflectance of an interference thin layer pattern in accordance with some implementations.

FIG. 12 is a graph illustrating an example of reflectances of a plurality of optical filters that provide the reflectance of FIG. 11 in accordance with some implementations.

FIG. 13 is a graph illustrating an example of a thickness distribution of a thin layer formed by a layer deposition apparatus according to a comparative example in accordance with some implementations.

FIG. 14A is a plan view illustrating an example of an interference thin layer pattern provided on an upper surface of a first chamber in accordance with some implementations.

FIG. 14B is a plan view illustrating an example of an interference thin layer pattern provided on an upper surface of a first chamber in accordance with some implementations.

FIG. 15 is a cross-sectional view illustrating an example of a layer deposition apparatus in accordance with some implementations.

FIG. 16 is a perspective view illustrating an example of a second interference thin layer pattern disposed on a lower surface of a second chamber of the layer deposition apparatus of FIG. 15 in accordance with some implementations.

FIG. 17 is a flow chart illustrating an example of a layer deposition method in accordance with some implementations.

### DETAILED DESCRIPTION

Hereinafter, example implementations will be explained in detail with reference to the accompanying drawings.

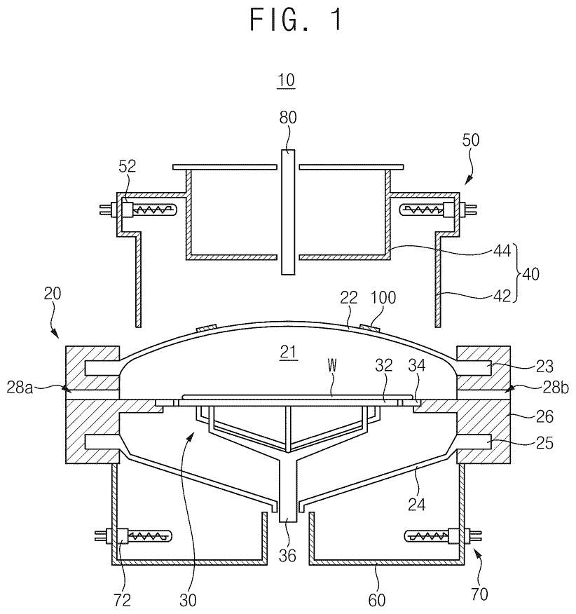

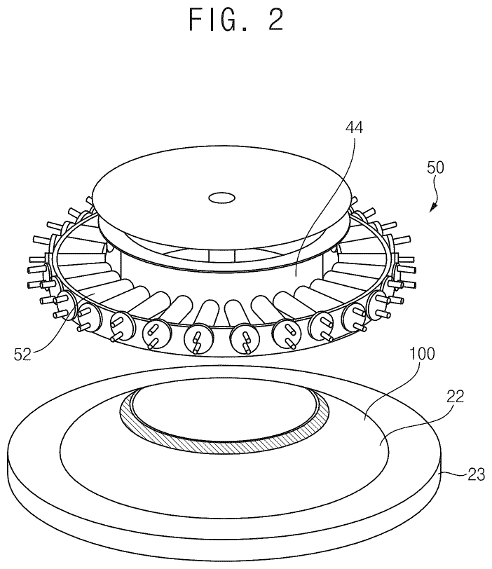

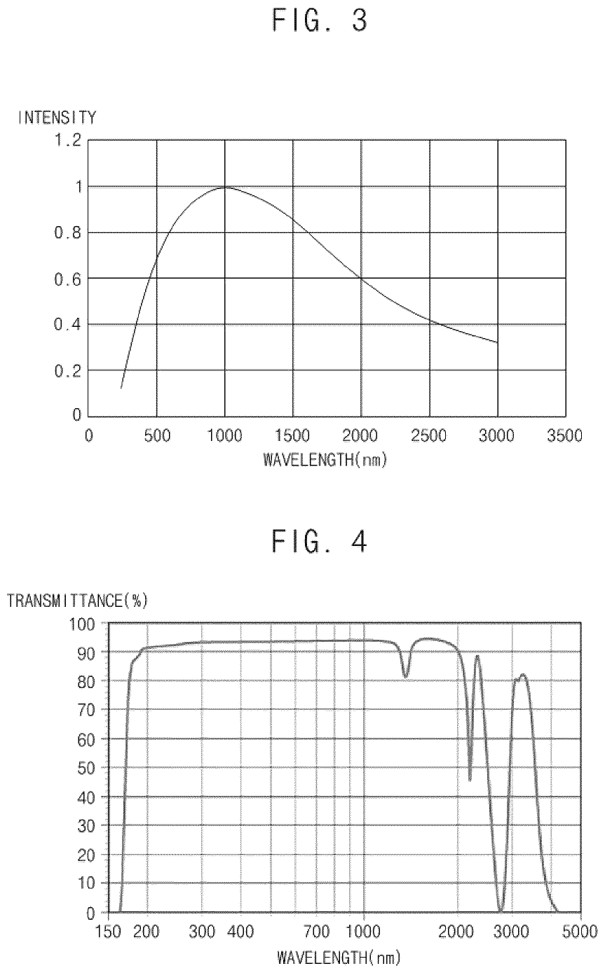

FIG. 1 is a cross-sectional view illustrating an example of a layer deposition apparatus in accordance with some implementations. FIG. 2 is a perspective view illustrating an example of a lamp heating portion including a plurality of light sources disposed in an upper portion of a first chamber of the layer deposition apparatus of FIG. 1 in accordance with some implementations. FIG. 3 is a graph illustrating an example of a spectrum according to wavelength of light emitted from the light source of FIG. 2 in accordance with some implementations. FIG. 4 is a graph illustrating an example of light transmittance of the first chamber with respect to light emitted from the light source of FIG. 2 in accordance with some implementations.

In FIG. 1 to 4, a layer deposition apparatus 10 includes a process chamber 20, a substrate support 30, a first reflection housing 40, a first lamp heating portion 50, and an interference thin layer pattern 100. Additionally, the layer deposition apparatus 10 may further include a second reflection housing 60, a second lamp heating portion 70, and a temperature measuring portion 80.

In some implementations, the layer deposition apparatus 10 may be an apparatus configured to perform a layer deposition process to form a thin layer on the substrate W. For example, the layer deposition apparatus 10 may include the process chamber 20 for performing a thermal process such as an epitaxial process. However, it may not be limited thereto, for example, the process chamber may provide a controlled thermal cycle that heats the substrate for processes, such as thermal annealing, thermal cleaning, thermal chemical vapor deposition, thermal oxidation, thermal nitridation, etc.

For example, the substrate may include silicon, silicon oxide, doped silicon, silicon germanium, germanium, gallium arsenide, glass, sapphire, and any other materials, such as metals, metal nitrides, metal alloys, and other conductive or semi-conductive materials. The substrate may not be limited to any particular size or shape. For example, the substrate may have a diameter of 200 mm or 300 mm, which is generally round, but is not limited thereto, and may have other shapes such as polygonal, squared, rectangular, curved shapes, etc.

The process chamber 20 may provide an inner space 21 for performing a process such as a layer deposition process on the substrate W. The process chamber 20 may include a first chamber 22 as an upper chamber and a second chamber 24 as a lower chamber. Abase ring 26 may be interposed between the first chamber 22 and the second chamber 24. The base ring 26 may surrounds edges of the first chamber 22 and the second chamber 24 and may couple the first chamber 22 and the second chamber 24. The first chamber 22 and the second chamber 24 may be coupled to the base ring 26 to define an inner space 21. An outer end portion 23 of the first chamber 22 and an outer end portion 25 of the second chamber 24 may be respectively attached to and supported on an inner portion of the base ring 26. For example, the first chamber 22 and the base ring 26 may be mechanically coupled to each other by an upper clamp ring.

When the substrate W is loaded/unloaded into the inner space 21, at least one of the first chamber 22 and the second chamber 24 may be separated from the base ring 26. For example, the substrate W may be loaded/unloaded through a slit door provided in the base ring 26. In some implementations, the base ring 26 may include an upper ring and a lower ring that are detachably fastened to each other.

The base ring 26 may have a gas inlet 28a and a gas outlet 28b. For example, the base ring 26 may have holes that connect the inner space to the outside of the process chamber 20, and the holes may be provided as the gas inlet 28a and the gas outlet 28b respectively. The gas inlet 28a may be formed in a first side of the base ring 26, and the gas outlet 28b may be formed in a second side of the base ring 26. The gas inlet 28a and the gas outlet 28b may be provided at positions opposite to each other. A process gas may be provided into the process chamber 20 through the gas inlet 28a. A gas within the process chamber 20 may be exhausted to the outside through the gas outlet 28b. The gas outlet 28b may be connected to a vacuum pump such that the space inside the process chamber 20 may be adjusted to a pressure of a desired vacuum degree. The process gas may include silane (SiH₄), disilane (Si₂H₆), DCS (SiH₂Cl₂), TCS (SiHCl₃), etc.

The first chamber 22 and the second chamber 24 may have a dome shape. The second chamber 24 may have a funnel shape. The first chamber 22 and the second chamber 24 may include an optically transparent material such as quartz. The first and second chambers 22 and 24 may be transparent to infrared radiation. For example, the first and second chambers 22 and 24 may include a transparent material capable of transmitting at least 90% of infrared radiation. The first and second chambers 22 and 24 may have a transmittance of at least 80% for light in a wavelength range of 200 nm to 2,000 nm.

The substrate support 30 may be disposed within the inner space 21 and may include a susceptor 32 as a substrate stage for supporting the substrate W and a susceptor support 36 to support and rotate the susceptor 32. The susceptor 32 may include a graphite material or a ceramic material coated with a silicon-based material, such as silicon carbide, or other process-resistant material.

Additionally, the substrate support 30 may further include a preheating ring 34 that is provided to surround the susceptor 32. The preheating ring 34 may preheat the process gas to a predetermined temperature. Accordingly, the process gas may be thermally decomposed into a gas form ready for epitaxial growth.

The susceptor support 36 may support the susceptor 32. The susceptor support 36 may elevate the susceptor 32 and may rotate the susceptor 32 on a central axis of the substrate W. For example, the susceptor 32 may rotate the substrate W at about 10 rpm to about 100 rpm. Because the susceptor 20 is rotated, an entire area of a substrate W may be uniformly processed.

The first reflection housing 40 may be disposed above the process chamber 10 outside the process chamber. The first reflection housing 40 may be disposed on the first chamber 22. The first reflection housing 40 may include a first upper reflector 42 and a second upper reflector 44. The first upper reflector 42 and the second upper reflector 44 may be coupled with each other to be provided as a reflector assembly. The first reflection housing 40 may reflect light such that the light irradiated from the first lamp heating portion 50 may be irradiated to a desired position such as the substrate W, the susceptor 32, or the preheating ring 34. The first reflection housing 40 may concentrate the light emitted from the first lamp heating portion 50 onto the substrate W. An inner surface of the first reflection housing 40 may be coated with a material having a high reflectivity.

The first lamp heating portion 50 may be disposed within the first reflection housing 40. The first lamp heating portion 50 may include a plurality of first light sources 52 as first heating lamps for irradiating light onto the substrate W through the first chamber 22. The plurality of first light sources 52 may be arranged along a circumferential direction of the first reflection housing 40. Light emitted from the first light sources 52 may pass through the first chamber 22 and may provide infrared radiant heat to the substrate W. The light emitted from the first light sources 52 may include infrared light. For example, each of the light sources 52 may include a halogen lamp.

A portion of the light from the first light sources 52 may pass through the first chamber 22 to be directly irradiated onto the substrate W, and another portion of the light from the first light sources 52 may be reflected in the reflection housing 40 and may pass through the upper chamber 12 to reach into the inner space 21. Accordingly, heat loss of the light may be minimized. Additionally, the plurality of first light sources 52 may be arranged along the circumferential direction of the first reflection housing 40 to increase thermal efficiency.

In FIG. 3, when the first light source 52 includes a halogen lamp, the light emitted from the first light source 52 may have a near-infrared (NIR) wavelength band. For example, the light emitted from the first light source 52 may have a bandwidth of 400 nm to 2300 nm.

In FIG. 4, a transmission characteristic curve of the first chamber 22 may have a transparent window in a range of from 200 nm to 2,000 nm. Accordingly, the effective wavelength range of light irradiated onto the substrate W through the first chamber 22 may be within a range of 800 nm to 2,000 nm. The first chamber 22 may have a transmittance of at least 80% for light in a wavelength range of 200 nm to 2,000 nm.

In FIG. 1, the second reflection housing 60 may be disposed under the process chamber 10. The second reflection housing 60 may be disposed below the second chamber 24. Similarly, to the first reflection housing 40, the second reflection housing 60 may include a plurality of lower reflectors that are coupled to each other to be provided as one reflector assembly. The second reflection housing 60 may reflect and concentrated light emitted by the second lamp heater 60 onto the substrate W. An inner surface of the second reflection housing 60 may be coated with a material having a high reflectivity.

The second lamp heating portion 70 may be disposed within the second reflection housing 60. The second lamp heater 70 may include a plurality of second light sources 72 as second heating lamps for irradiating light onto the substrate W through the second chamber 24. A plurality of second light sources 72 may be arranged along a circumferential direction of the second reflection housing 60. Light emitted from the second light sources 72 may pass through the second chamber 24 and may provide infrared radiant heat to the substrate W. The light emitted from the second light sources 72 may be reflected within the second reflection housing 60 and may pass through the second chamber 24 to reach into the inner space 21. For example, each of the second light sources 72 may include a halogen lamp.

In some implementations, the temperature measuring portion 80 may be disposed to face a top surface of the substrate W. The temperature measuring portion 80 may be arranged to correspond to the central axis of the substrate W. The temperature measuring portion 80 may measure a temperature of a heating area of the substrate W. For example, the temperature measuring portion 80 may include a pyrometer and a radiation temperature sensor. The temperature measuring portion 50 may include a plurality of the radiation temperature sensors.

In some implementations, the interference thin layer pattern 100 may be disposed on an upper surface of the first chamber 22. The interference thin layer pattern 100 may have an annular shape and may cover an annular area at a specific radius of the upper surface of the first chamber 22 to prevent a light overlap phenomenon in which lights overlap intensively in some areas on the substrate W.

Hereinafter, the interference thin layer pattern will be described in detail.

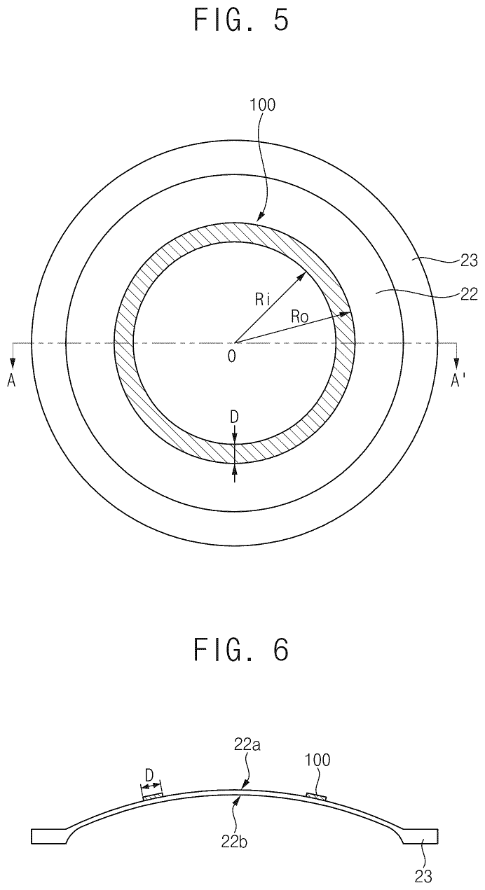

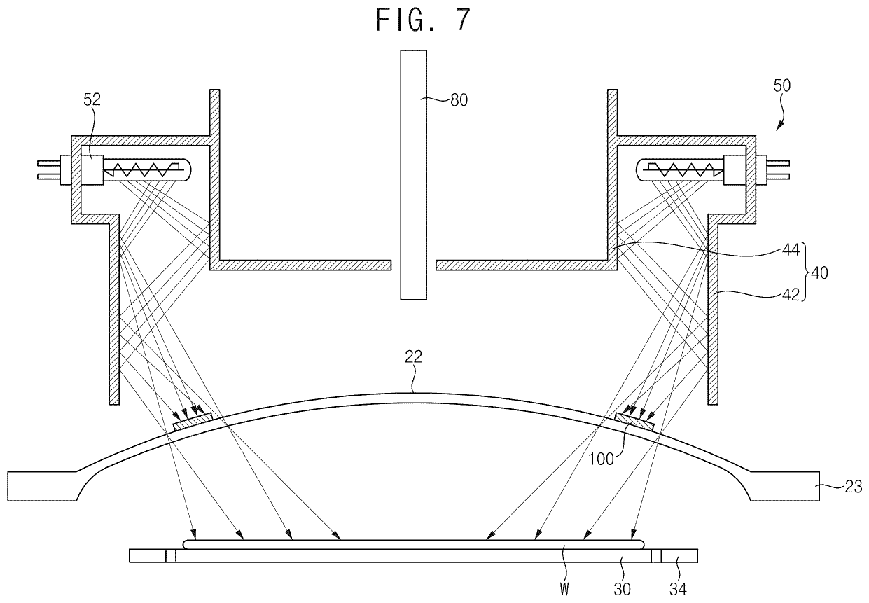

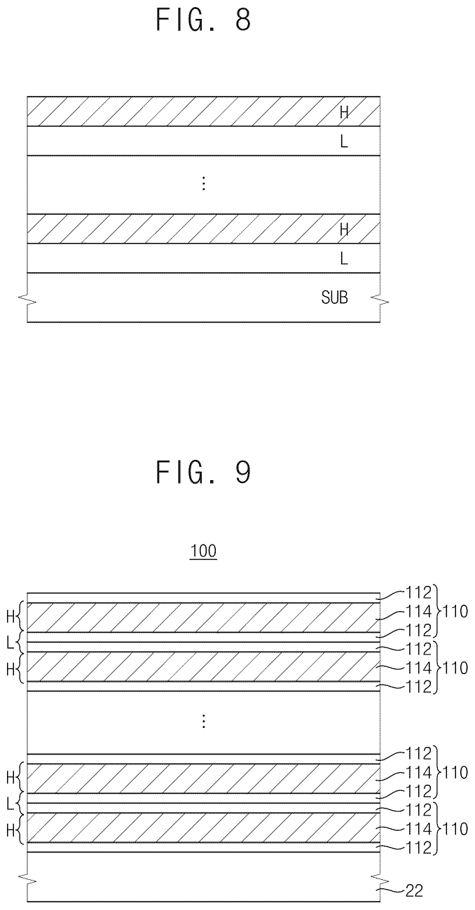

FIG. 5 is a plan view illustrating an example of an interference thin layer pattern provided on an upper surface of a first chamber in accordance with some implementations. FIG. 6 is a cross-sectional view taken along the line A-A′ in FIG. 5 in accordance with some implementations. FIG. 7 is a cross-sectional view illustrating the interference thin layer pattern of FIG. 5 that blocks some of the light from the first light sources in accordance with some implementations. FIG. 8 is a cross-sectional view illustrating an example of an interference thin layer pattern in which first thin layers and second thin layers are alternately stacked on a transparent substrate in accordance with some implementations. FIG. 9 is a cross-sectional view illustrating an example of an interference thin layer pattern formed on the upper surface of the first chamber in accordance with some implementations.

In FIGS. 5 to 9, an interference thin layer pattern 100 may have an annular shape and may cover an annular area at a specific radius of an upper surface 22a of a first chamber 22. An inner diameter Ri of the interference thin layer pattern 100 from a center O of the first chamber 22 may be within a range of 60 mm to 130 mm, and an outer diameter Ro of the interference thin layer pattern 100 may be within a range of 90 mm to 150 mm. The interference thin layer pattern 100 may have a width D within a range of 5 mm to 80 mm. The interference thin layer pattern 100 may have a thickness within a range of 0.4 μm to 10 μm.

In FIG. 8, the interference thin layer pattern 100 has a multilayer structure in which a first thin layer with a low refractive index L and a second thin layer with a high refractive index H are alternately stacked on a transparent substrate SUB. To maximize or minimize interference, an optical thickness of each thin layer may be λ/4 of a reference wavelength λ(QWOT, quarter-wave optical thickness) or λ/2 of the reference wavelength λ (HWOT, half-wave optical thickness). When the thin layers have an optical thickness of λ/4, a reflectance of the interference thin layer pattern 100 may be expressed as following Equation (1):

Here, R is the reflectance, n_{H} is the high refractive index, n_{L} is the low refractive index,

$$R = {( \frac{1 - {( \frac{{n}_{H}}{{n}_{L}} )}^{2 S} ( \frac{{n}_{H}^{2}}{{n}_{sub}} )}{1 + {( \frac{{n}_{H}}{{n}_{L}} )}^{2 S} ( \frac{{n}_{H}^{2}}{{n}_{sub}} )} )}^{2}$$

and S represents the number of layers including the first and second thin layers stacked.

In FIG. 9, the interference thin layer pattern 100 may include a plurality of unit stack layers 110 sequentially stacked on the upper surface of the upper chamber 22. Each unit stack layer 110 may include a first thin layer 112, a second thin layer 114 stacked on the first thin layer 112, and a first thin layer 112 stacked on the second thin layer 114. The first thin layer 112 may have a first refractive index n_{L}, and the second thin layer 114 may have a second refractive index n_{H} that is greater than the first refractive index.

The optical thickness of the first thin layer 112 may be λ/4 of the reference wavelength λ, and the optical thickness of the second thin layer 114 may be λ/2 of the reference wavelength λ. The interference thin layer pattern 100 may include several to tens of layers of unit stack layers 110. The stacked number of the unit stack layers, the total thickness of the interference thin layer pattern, the width and an area ratio of the interference thin layer pattern may be determined in consideration of a desired interference effect, such as reflectivity, effective bandwidth, etc., the optical and geometric thin layer thicknesses of the first and second thin layers.

For example, the first thin layer 112 may include silicon oxide (SiO₂), aluminum oxide (Al₂O₃), silicon nitride (SiN), etc. The second thin layer 114 may include zinc oxide (ZnO), titanium oxide (TiO₂), tantalum pentoxide (Ta₂O₅), fluorine doped tin oxide (FTO), antimony tin oxide (ATO), indium tin oxide (ITO), indium antimony tin oxide (IATO), aluminum doped zinc oxide (AZO), etc.

In some implementations, the interference thin layer pattern 100 may serve as an optical filter having a reflection bandwidth with respect to a reference wavelength. The optical thicknesses, geometric thin layer thicknesses, and refractive indices of the first and second thin layers that are alternately stacked may be important factors affecting the characteristics of the optical filter.

Hereinafter, optical characteristics of the interference thin layer pattern will be described.

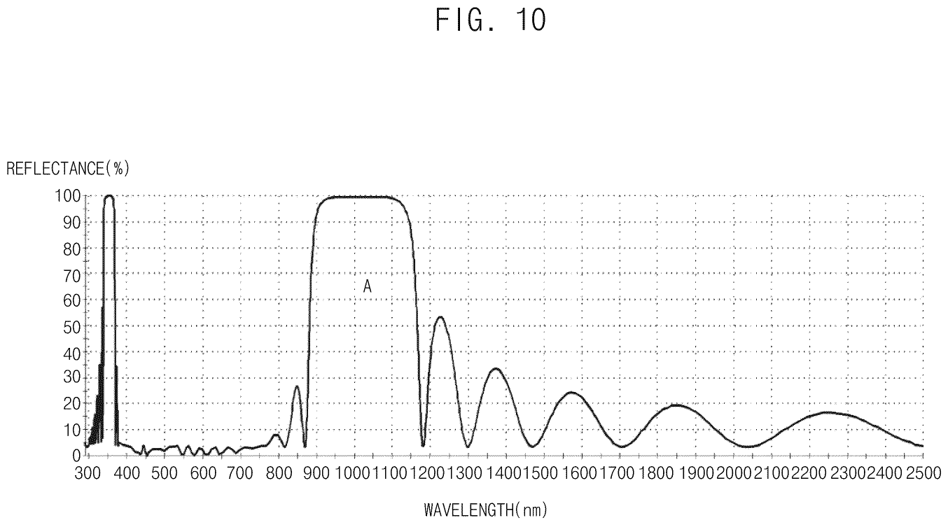

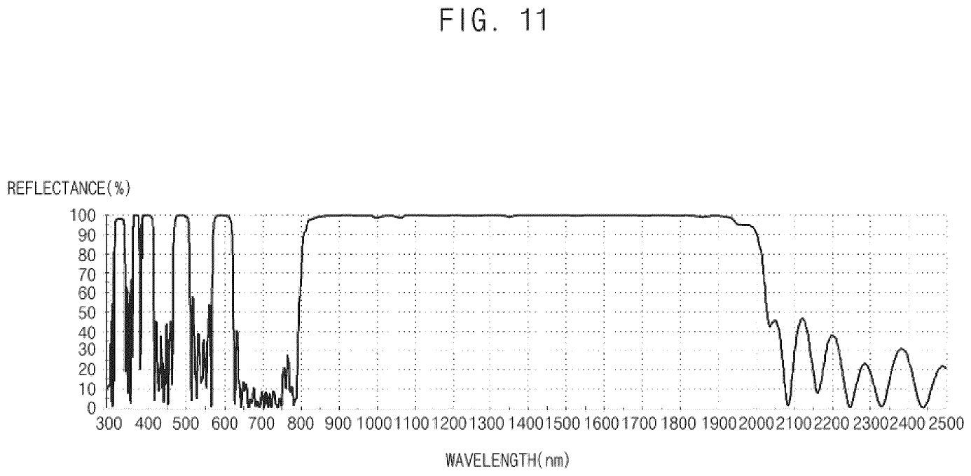

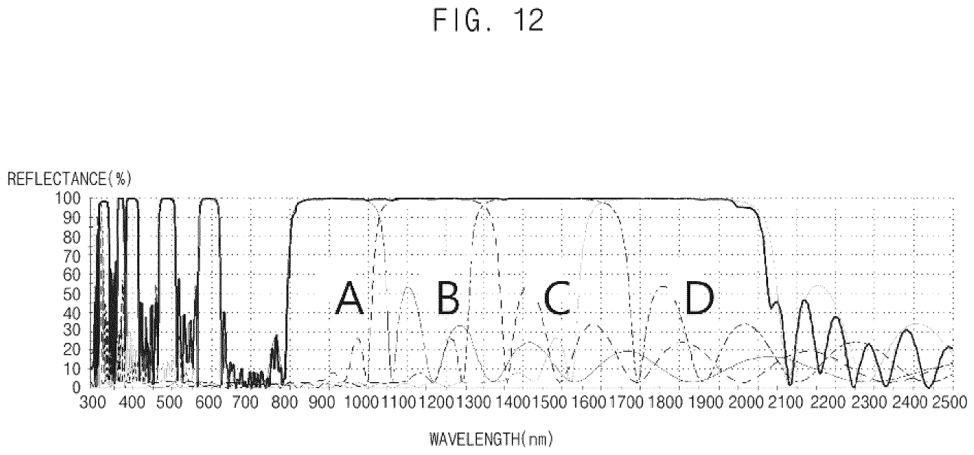

FIG. 10 is a graph illustrating an example of reflectance of an interference thin layer pattern in accordance with some implementations, wherein the interference thin layer pattern has optical filter characteristics according to a first coefficient constant for a first reference wavelength. FIG. 11 is a graph illustrating an example of reflectance of an interference thin layer pattern in accordance with some implementations. FIG. 12 is a graph illustrating an example of reflectances of a plurality of optical filters that provide the reflectance of FIG. 11 in accordance with some implementations.

In FIGS. 10 to 12, a reflection bandwidth and reflectance of the interference thin layer pattern 100 may be determined by an optical thickness, a geometric thin layer thickness, etc. of the first thin layer 112 and the second thin layer 114. The interference thin layer pattern 100 may function as an optical filter having a specific coefficient constant for a specific reference wavelength. The interference thin layer pattern 100 may serve as an optical filter in which optical characteristics of a plurality of coefficient constants respectively determined for a plurality of reference wavelengths are overlapped.

In FIG. 10, when a unit stack layer 110 of the interference thin film pattern 100 has a structure in which the unit stack layers 110 of [low refractive index (L/2)/high refractive index (H)/low refractive index (L/2)] structure are stacked in eight layers, the interference thin layer pattern 100 may have optical filter characteristics with a first coefficient constant A of a first reference wavelength.

In FIGS. 11 and 12, the interference thin layer pattern 100 including eight layers of unit stack layers 110 may have first to fourth optical filter characteristics with first to fourth coefficient constants A, B, C and D for first to fourth reference wavelengths. The first to fourth optical filter characteristics may be overlapped to provide one optical filter having reflectance of at least 90% in a wavelength bandwidth of 800 nm to 2,000 nm. The reflectance of the interference thin layer pattern 100 in a wavelength bandwidth of 800 nm to 2,000 nm may be expressed by following Equation (2):

(A(0.5 L H0.5 L))^{s}(B(0.5 L H0.5 L))^{s}(C(0.5 L H0.5 L))^{s}(D(0.5 L H0.5 L))^{s}

Here, A=0.899, B=1.151, C=1.435, D=1.761, and S is 8.

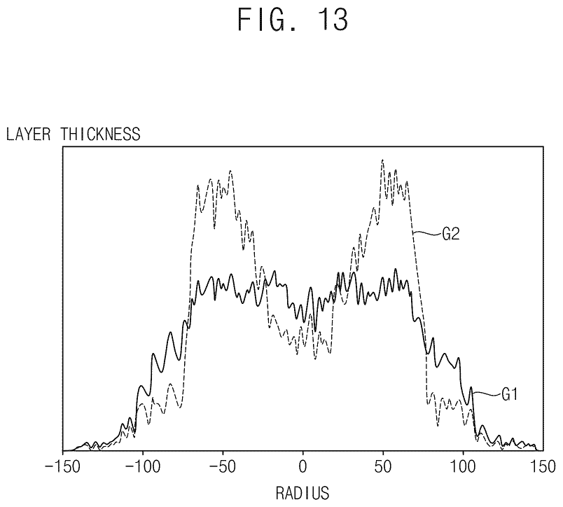

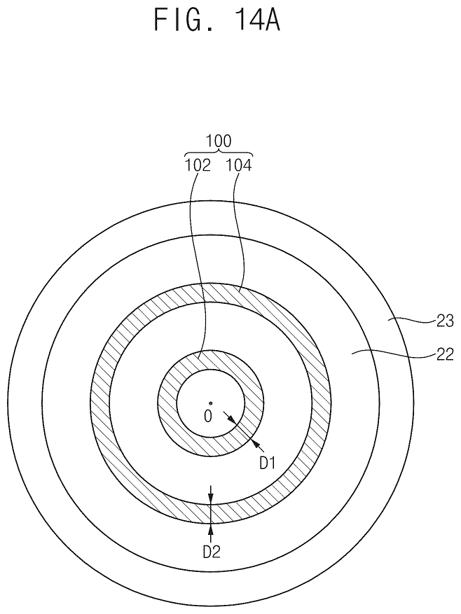

FIG. 13 is a graph illustrating an example of a thickness distribution of a thin layer formed by a layer deposition apparatus according to a comparative example and in accordance with some implementations. In FIG. 13, graph G1 represents a thickness of a thin layer formed by a layer deposition apparatus having an interference thin layer pattern in accordance with some implementations, and graph G2 represents a thickness of a thin layer formed by a layer deposition apparatus without an interference thin layer pattern according to a comparative example in accordance with some implementations. It can be seen that due to the interference thin layer pattern, the thickness of the thin layer in the middle region of the wafer radius of about 100 mm relatively decreases, and the thickness of the thin layer in other regions relatively increases.

During an epitaxial process, the substrate W may be heated to a preset temperature of about 750° C. or less. Despite a precise control of heating the substrate W, light from the first light sources 52 may be reflected within the first reflection housing 40 and may overlap intensively in one or more areas on the substrate W, for example, a middle region with a wafer radius of about 100 mm, thereby causing temperature unevenness. The interference thin layer pattern 100 may cover an annular area at a specific radius of the upper surface of the first chamber 22 to prevent a light overlap phenomenon in which lights overlap intensively in some areas on the substrate W. Accordingly, a uniform thin layer may be formed on the wafer.

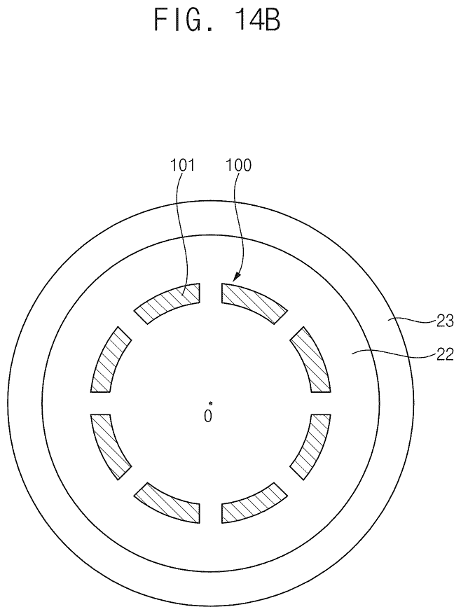

FIG. 14A is a plan view illustrating an example of an interference thin layer pattern provided on an upper surface of a first chamber in accordance with some implementations. In FIG. 14A, an interference thin layer pattern 100 may include a first thin layer pattern 102 and a second thin layer pattern 104. The first and second thin layer patterns 102 and 104 may be spaced apart from each other along concentric circles having different radii. The first thin layer pattern 102 may have an annular shape extending along a concentric circle having a first radius, and the second thin layer pattern 104 may have an annular shape extending along a concentric circle having a second radius greater than the first radius.

Each of the first thin layer pattern 102 and the second thin layer pattern 104 may include a multilayer layer in which first thin layers and second thin layers having different refractive indices are alternately stacked. Each of the first thin layer pattern 102 and the second thin layer pattern 104 may include a plurality of unit stack layers sequentially stacked on the upper surface of the upper chamber 22, and each of the unit stack layers may include a first thin layer having a first refractive index, a second thin layer stacked on the first thin layer and having a second refractive index greater than the first refractive index, and the first thin layer stacked on the second thin layer.

The first thin layer pattern 102 may have a first width D1, and the second thin layer pattern 104 may have a second width D2 that is different from the first width. Optical thicknesses and geometric thin layer thicknesses of the first thin layer and the second thin layer of the first thin layer pattern 102 may be the same or different from optical thicknesses and geometric thin layer thicknesses of the first thin layer and of the second thin layer pattern 104. The first thin layer pattern 102 may have a first reflectance in a first wavelength band, and the second thin layer pattern 102 may have a second reflectance different in the first wavelength band from the first reflectance.

FIG. 14B is a plan view illustrating an example of an interference thin layer pattern provided on an upper surface of a first chamber in accordance with some implementations. In FIG. 14B, an interference thin layer pattern 100 may include a plurality of thin layer patterns 101 extending along a concentric circle having a first radius. The plurality of thin layer patterns 101 may be arranged at equal or different intervals from each other along a circumferential direction.

Each of the plurality of thin layer patterns 101 may include a multilayer layer in which first thin layers and second thin layers having different refractive indices are alternately stacked. The thin layer pattern 101 may include a plurality of unit stack layers sequentially stacked on an upper surface of an upper chamber 22, and each of the unit stack layers may include a first thin layer having a first refractive index, a second thin layer having a second refractive index greater than the first refractive index, and the first thin layer stacked on the second thin layer.

The first thin layer and the second thin layer of the plurality of thin layer patterns 101 may have the same or different optical thickness and geometric thin layer thickness. The plurality of thin layer patterns 101 may have the same or different reflectance.

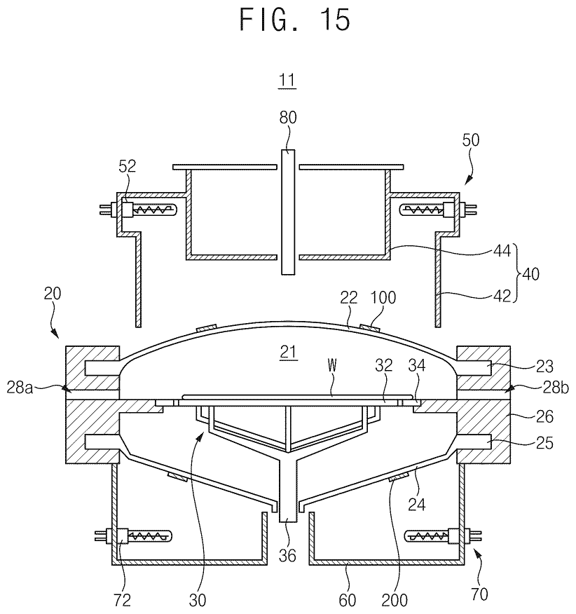

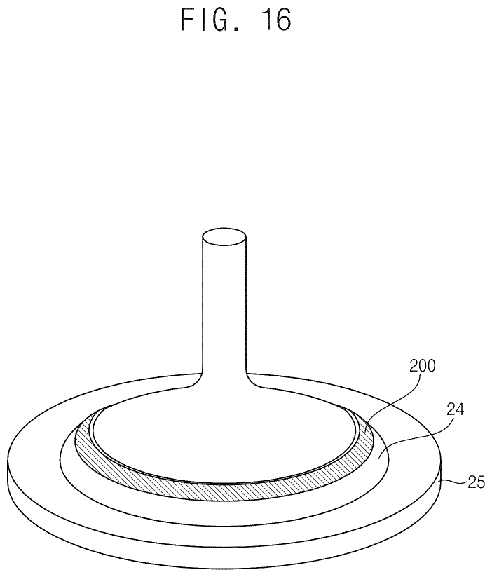

FIG. 15 is a cross-sectional view illustrating an example of a layer deposition apparatus in accordance with some implementations. FIG. 16 is a perspective view illustrating an example of a second interference thin layer pattern disposed on a lower surface of a second chamber of the layer deposition apparatus of FIG. 15 in accordance with some implementations. The layer deposition apparatus may be substantially the same as or similar to the layer deposition apparatus described with reference to FIG. 1 except for an additional second interference the layer pattern. Accordingly, same reference numerals will be used to refer to the same or like elements and any further repetitive explanation concerning the above elements will be omitted.

In FIGS. 15 and 16, a layer deposition apparatus 11 may include a process chamber 20, a substrate support 30, a first reflection housing 40, a first lamp heating portion 50, a second reflection housing 60, a second lamp heating portion 70, a first interference thin layer pattern 100, and a second interference thin layer pattern 200.

In some implementations, the first interference thin layer pattern 100 may be disposed on an upper surface of the first chamber 22. The first interference thin layer pattern 100 may have an annular shape and may cover an annular area at a specific radius of the upper surface 22a of the first chamber 22. The first interference thin layer pattern 100 may have a first reflectance in a wavelength bandwidth of 800 nm to 2000 nm. The first interference thin layer pattern 100 may function as an optical filter having a reflectance of at least 30% in a wavelength bandwidth of 800 nm to 2,000 nm. The first interference thin layer pattern 100 may prevent a light overlap phenomenon in which light from first light sources 52 intensively overlaps in some areas on the substrate W.

The second interference thin layer pattern 200 may be disposed on a lower surface of the second chamber 24. The second interference thin layer pattern 200 may have an annular shape and may cover an annular area at a specific radius of the lower surface of the second chamber 24. The second interference thin layer pattern 200 may have a second reflectance in a wavelength bandwidth of 800 nm to 2000 nm. The second interference thin layer pattern 200 may function as an optical filter having a reflectance of at least 30% in a wavelength bandwidth of 800 nm to 2,000 nm. The second interference thin layer pattern 200 may prevent a light overlap phenomenon in which light from second light sources 72 intensively overlaps in some areas on the substrate W.

For example, the first reflectance may be the same as or different from the second reflectance. When the first reflectance of the first interference thin layer pattern 100 is 70%, the second reflectance of the second interference thin layer pattern 200 may be 30%. When the first reflectance of the first interference thin layer pattern 100 may be 50%, the second reflectance of the second interference thin layer pattern 200 may be 50%. When the first reflectance of the first interference thin layer pattern 100 is 30%, the second reflectance of the second interference thin layer pattern 200 may be 70%. In order to obtain a uniform temperature distribution on the wafer, the first reflectance of the first interference thin layer pattern 100 and the second reflectivity of the second interference thin layer pattern 200 may be selected to be the same as or different from each other.

In some implementations, the second interference thin layer pattern 200 may have a ring-shaped pattern extending along one concentric circle, but may be limited thereto. For example, the second interference thin layer pattern 200 may include a plurality of thin layer patterns spaced apart from each other along concentric circles having different radii. The plurality of thin layer patterns may have an annular shape extending along concentric circles with specific radii. In some implementations, the second interference thin layer pattern 200 may include a plurality of thin layer patterns arranged at equal or different intervals from each other along a circumferential direction.

Hereinafter, a method of forming a thin layer on a wafer using the layer deposition apparatus of FIGS. 1 and 15 will be described.

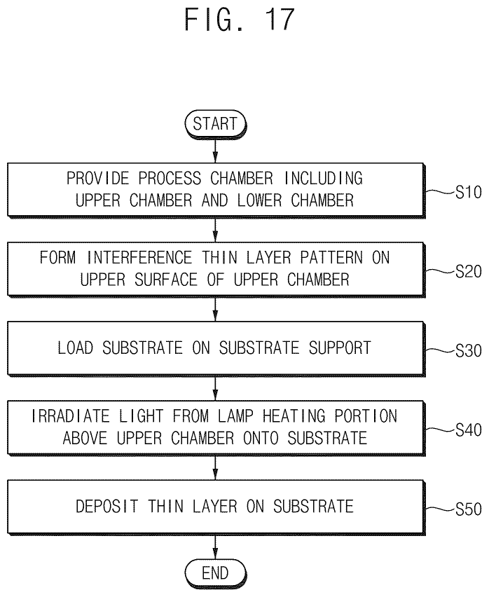

FIG. 17 is a flow chart illustrating an example of a layer deposition method in accordance with some implementations. In FIGS. 1 to 17, first, a process chamber 20 including an upper chamber 22 and a lower chamber 24 may be provided (S10), and an interference thin layer pattern 100 may be formed on an upper surface 22a of the upper chamber 22 (S20).

In some implementations, the process chamber 20 may provide an inner space 21 for performing a process such as a layer deposition process on the substrate W. The process chamber 20 may include a first chamber 22 as the upper chamber and a second chamber 24 as the lower chamber. A base ring 26 may be interposed between the first chamber 22 and the second chamber 24. The base ring 26 may surrounds edges of the first chamber 22 and the second chamber 24 and may couple the first chamber 22 and the second chamber 24. The first chamber 22 and the second chamber 24 may be coupled to the base ring 26 to define the inner space 21.

The first interference thin layer pattern 100 may be disposed on the upper surface of the first chamber 22. The interference thin layer pattern 100 may have an annular shape and may cover an annular area at a specific radius of the upper surface 22a of the first chamber 22. The interference thin layer pattern 100 may have a multilayer structure in which first thin layers having a low refractive index (L) and second thin layers having a high refractive index (H) are alternately stacked.

In FIG. 9, the interference thin layer pattern 100 may include a plurality of unit stack layers 110 that are sequentially stacked on the upper surface of the upper chamber 22. Each unit stack layer 110 may include a first thin layer 112, a second thin layer 114 stacked on the first thin layer 112, and a first thin layer 112 stacked on the second thin layer 114. The first thin layer 112 may have a first refractive index (n_{L}), and the second thin layer 114 may have a second refractive index (n_{H}) that is greater than the first refractive index. An optical thickness of the first thin layer 112 may be λ/4 of a reference wavelength k, and an optical thickness of the second thin layer 114 may be λ/2 of the reference wavelength k. The interference thin layer pattern 100 may include several to tens of layers of unit stack layers 110.

Then, the substrate W may be loaded on a substrate support 30 within the process chamber 20 (S30). For example, when the substrate W is loaded into the inner space 21 of the process chamber 20, at least one of the first chamber 22 and the second chamber 24 may be separated from the base ring 26. For example, the substrate W may be loaded/unloaded through a slit door provided in the base ring 26.

Then, light from a lamp heater 50 disposed above the upper chamber 22 may be irradiated onto the substrate W (S40), and a thin layer may be deposited on the substrate W (S50).

In some implementations, the first lamp heating portion 50 may include a plurality of first light sources 52 as first heating lamps for irradiating light onto the substrate W through the upper chamber 22. The plurality of first light sources 52 may be arranged along a circumferential direction of a first reflection housing 40 disposed above the upper chamber 22. Light irradiated from the first light sources 52 may pass through the first chamber 22 and may provide infrared radiant heat to the substrate W. For example, each of the first light sources 52 may include a halogen lamp.

A portion of the light from the first light sources 52 may passes through the upper chamber 22 to be directly irradiated onto the substrate W, and another portion of the light from the first light sources 52 may be reflected in the reflection housing 40 and may pass through the upper chamber 22 to reach into the inner space 21. Accordingly, heat loss of the light may be minimized. Additionally, the plurality of first light sources 52 may be arranged along the circumferential direction of the first reflection housing 40 to increase thermal efficiency.

The second lamp heating portion 70 may include a plurality of second light sources 72 as second heating lamps for irradiating light onto the substrate W through the lower chamber 24. The plurality of second light sources 72 may be arranged along a circumferential direction of the second first reflection housing 60 disposed below the lower chamber 24. Light irradiated from the second light sources 72 may pass through the lower chamber 24 and may provide infrared radiant heat to the substrate W. For example, each of the second light sources 72 may include a halogen lamp.

A portion of the light from the second light sources 72 may pass through the lower chamber 24 to be directly irradiated onto the substrate W, and another portion of the light from the second light sources 72 may be reflected in the second reflection housing 60 and may pass through the lower chamber 24 to reach into the inner space 21.

After light is irradiated on the substrate W loaded on the substrate support 30, a process gas may be supplied into the process chamber 20 through a gas inlet 28a. A gas within the process chamber 20 may be exhausted to the outside through a gas discharge portion 28b. The gas discharge unit 28b may be connected to a vacuum pump such that the inner space inside the process chamber 20 may be adjusted to a pressure of a desired vacuum degree. The process gas may include silane (SiH₄), disilane (Si₂H₆), DCS (SiH₂Cl₂), TCS (SiHCl₃), etc.

During an epitaxial process, the substrate W may be heated to a preset temperature of about 750° C. or less. Despite a precise control of heating the substrate W, light from the first light sources 52 may be reflected within the first reflection housing 40 and may overlap intensively in one or more areas on the substrate W, for example, a middle region with a wafer radius of about 100 mm, thereby causing temperature unevenness.

The first interference thin layer pattern 100 may cover an annular area at a specific radius of the upper surface of the upper chamber 22 to prevent a light overlap phenomenon in which light is intensively overlapped in some areas on the substrate W. Accordingly, a uniform thin layer may be formed on the wafer.

Additionally, the second interference thin layer pattern 200 may be disposed on the lower surface of the second chamber 24. The second interference thin layer pattern 200 may have an annular shape and may cover an annular area at a specific radius of the lower surface of the second chamber 24. The second interference thin layer pattern 200 may have a multilayer structure in which first thin layers having a low refractive index (L) and second thin layers having a high refractive index (H) are alternately stacked.

The second interference thin layer pattern 200 may cover an annular area at a specific radius of the lower surface of the lower chamber 24 to prevent a light overlap phenomenon in which light is intensively overlapped in some areas on the substrate W.

Semiconductor devices formed using the above-described layer deposition apparatus and layer deposition method may be used in various types of systems, such as computing systems. In some implementations, the semiconductor device may include fin FET, DRAM, VNAND, etc. The system may be applied to computers, portable computers, laptop computers, personal digital assistants, tablets, mobile phones, digital music players, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. A deposition apparatus, comprising:
a process chamber configured having a space for processing a substrate, the process chamber including an upper chamber and a lower chamber that define an inner space;
a substrate support disposed within the process chamber and configured to support the substrate;
a first lamp heating portion disposed above the upper chamber and outside the process chamber, the first lamp heating portion including a plurality of first light sources configured to irradiate light onto the substrate through the upper chamber; and
an interference layer pattern disposed on an upper surface of the upper chamber and configured to reflect at least a portion of light from the plurality of first light sources.

2. The deposition apparatus of claim 1, wherein light emitted from the plurality of light sources has a bandwidth of 400 nm to 2,300 nm.

3. The deposition apparatus of claim 2, wherein the upper chamber has a transmittance of at least 80% for light in a wavelength range of 200 nm to 2,000 nm.

4. The deposition apparatus of claim 1, wherein the interference layer pattern includes a multilayer layer in which first layers and second layers having different refractive indices are alternately stacked.

5. The deposition apparatus of claim 4, wherein each of the first layers has a first refractive index, and each of the second layers has a second refractive index greater than the first refractive index.

6. The deposition apparatus of claim 5, wherein the first layer includes at least one of silicon oxide (SiO₂), aluminum oxide (Al₂O₃) and silicon nitride (SiN), and the second layer includes at least one of zinc oxide (ZnO), titanium oxide (TiO₂), tantalum pentoxide (Ta₂O₅), fluorine tin oxide (FTO), antimony tin oxide (ATO), indium tin oxide (ITO), indium antimony tin oxide (IATO) and aluminum doped zinc oxide (AZO).

7. The deposition apparatus of claim 1,
wherein the interference layer pattern includes a plurality of unit stack layers sequentially stacked on the upper surface of the upper chamber, and
wherein each unit stack layer includes:
a first layer having a first refractive index;
a second layer stacked on the first layer and having a second refractive index greater than the first refractive index; and
wherein the first layer is stacked on the second layer.

8. The deposition apparatus of claim 7, wherein an optical thickness of the first layer is λ/4 of a reference wavelength a, and an optical thickness of the second layer is λ/2 of the reference wavelength a.

9. The deposition apparatus of claim 1, wherein the interference layer pattern has a reflectance of at least 50% in a wavelength bandwidth of 800 nm to 2,000 nm.

10. The deposition apparatus of claim 1, further comprising:
a second lamp heating portion disposed below the lower chamber and outside the process chamber, the second lamp heating portion including a plurality of second light sources configured to irradiate light onto the substrate through the lower chamber; and
a second interference layer pattern disposed on a lower surface of the lower chamber and configured to reflect at least a portion of light from the plurality of second light sources.

11. A deposition apparatus, comprising:
a first transparent chamber having a dome shape;
a second transparent chamber having a dome shape;
a substrate support disposed between the first transparent chamber and the second transparent chamber, the substrate support being configured to support a substrate;
a first lamp heating portion disposed above the first transparent chamber and including a plurality of first light sources configured to irradiate light onto the substrate through the first transparent chamber; and
an interference layer pattern disposed on an upper surface of the first transparent chamber, the interference layer pattern including first layers and second layers having different refractive indexes that are alternately stacked to reflect at least a portion of light from the plurality of light sources.

12. The deposition apparatus of claim 11, wherein light emitted from the plurality of light sources has a bandwidth of 400 nm to 2,300 nm.

13. The deposition apparatus of claim 12, wherein the first transparent chamber has a transmittance of at least 80% for light in a wavelength range of 200 nm to 2000 nm.

14. The deposition apparatus of claim 11, wherein each of the first layers has a first refractive index, and each of the second layers has a second refractive index greater than the first refractive index.

15. The deposition apparatus of claim 14, wherein the first layer includes at least one of silicon oxide (SiO₂), aluminum oxide (Al₂O₃) and silicon nitride (SiN), and the second layer includes at least one of zinc oxide (ZnO), titanium oxide (TiO₂), tantalum pentoxide (Ta₂O₅), fluorine tin oxide (FTO), antimony tin oxide (ATO), indium tin oxide (ITO), indium antimony tin oxide (IATO) and aluminum doped zinc oxide (AZO).

16. The deposition apparatus of claim 11,
wherein the interference layer pattern includes a plurality of unit stack layers sequentially stacked on the upper surface of the first transparent chamber, and
wherein each unit stacked layer includes:
the first layers stacked in an alternating pattern with the second layers, wherein the first layers have a first refractive index, and
the second layers have a second refractive index greater than the first refractive index.

17. The deposition apparatus of claim 16, wherein an optical thickness of each first layer is λ/4 of a reference wavelength a, and an optical thickness of each second layer is λ/2 of the reference wavelength a.

18. The deposition apparatus of claim 11, wherein the interference layer pattern has a thickness within a range of 0.4 μm to 10 μm.

19. The deposition apparatus of claim 11, wherein the interference layer pattern has a reflectance of at least 50% in a wavelength bandwidth of 800 nm to 2,000 nm.

20. The deposition apparatus of claim 11, further comprising:
a second lamp heating portion disposed below and outside of the second transparent chamber, the second lamp heating portion including a plurality of second light sources configured to irradiate light onto the substrate through the second transparent chamber; and
a second interference layer pattern disposed on a lower surface of the second transparent chamber and configured to reflect at least a portion of light from the plurality of second light sources.

21-30. (canceled)
